(19) United States
(12) Patent Application Publication
(10) Pub. No.: US 2025/0305116 A1
(43) Pub. Date: Oct. 2, 2025

(54) APPARATUS FOR PRODUCING GRAPHENE MEMBRANE

(71) Applicant: AirMembrane Corporation, Tsukuba (JP)

(72) Inventors: Masataka Hasegawa, Tsukuba (JP); Shunsuke Kawaki, Tsukuba (JP)

(73) Assignee: AirMembrane Corporation, Tsukuba (JP)

(21) Appl. No.: 19/091,111

(22) Filed: Mar. 26, 2025

Related U.S. Application Data
(60) Provisional application No. 63/570,269, filed on Mar. 27, 2024.

(51) Int. Cl. C23C 16/26; C23C 16/46; C23C 16/54

(52) U.S. Cl. CPC C23C 16/26; C23C 16/46; C23C 16/545

(57) ABSTRACT

A graphene film manufacturing device is equipped with a plasma generating device in a processing vessel, a metal substrate for graphene film formation installed in the processing vessel and a device for continuously sending and winding it, a Joule heating device for Joule heating the metal substrate for graphene film formation installed in the processing vessel, and a substrate cover for covering the metal substrate for graphene film formation. An opening may be provided in the substrate cover, and the position and/or length of the opening are set according to the winding speed of the metal substrate that is heated by Joule heating while being continuously wound up.

This application claims benefits based on Provisional Application No. 63/570,269 filed on Mar. 27, 2024, the entire content of which is incorporated herein by reference.

### TECHNICAL FIELD

The present invention relates to a graphene film manufacturing device for use in transparent conductive films, etc.

### BACKGROUND ART

A conductive planar crystal made of sp2-bonded carbon atoms is called “graphene.” Graphene is described in detail in Non-Patent Document 1. Graphene is the basic unit of crystalline carbon films of various forms. Examples of crystalline carbon films made of graphene include single-layer graphene made of a single layer of graphene, nanographene, which is a stack of several to tens of nanometer-sized graphene layers, and carbon nanowalls (see Non-Patent Document 2), in which several to tens of graphene layers are oriented at an angle close to perpendicular to the substrate surface.

Crystalline carbon films made of graphene are expected to be used as transparent conductive films and transparent electrodes due to their high light transmittance and electrical conductivity. Furthermore, the carrier mobility of electrons and holes in graphene can be as high as 200,000 cm²/Vs at room temperature, 100 times higher than that of silicon. Taking advantage of the properties of graphene, high-frequency devices and highly sensitive sensors that operate at terahertz (THz) frequencies are also being developed.

So far, methods for producing graphene transparent conductive films have been developed, including peeling from natural graphite, removing silicon by high-temperature heat treatment of silicon carbide, and forming films on various metal surfaces. However, a wide range of industrial applications of transparent conductive carbon films using graphene crystalline carbon films are being considered, and therefore a method for forming large-area films with high throughput is desired.

As one method for forming a graphene transparent conductive film, a method using chemical vapor deposition (CVD) on the surface of copper foil has been developed (see Non-Patent Documents 3 and 4). This graphene film formation method using copper foil as a substrate is based on a thermal CVD method, in which methane gas, a raw material gas, is thermally decomposed at about 1000° C. to form a layer of graphene on the surface of the copper foil. However, in the graphene production method using the thermal CVD method, a gaseous raw material such as methane gas is basically decomposed by contacting it with heated copper foil, but since the decomposition efficiency is low, it takes at least 30 minutes, usually one hour to several hours, to form a layer of graphene on the copper foil. Therefore, to realize the industrial use of graphene, it is necessary to develop a graphene synthesis method that can be performed in a shorter time. In addition, this method is basically a batch process in which after graphene is synthesized on one copper foil substrate, the substrate is replaced and the next graphene is synthesized, so there was a need to develop a continuous synthesis method such as a roll-to-roll method that is more suitable for mass production.

The method of continuously synthesizing a thin film on the surface of a substrate by a so-called roll-to-roll method while winding up a substrate for film formation has been used in various fields of industrial use of thin films, but in recent years, attempts have been made to apply it as a high-throughput continuous synthesis method for graphene (Patent Documents 1, 2, Non-Patent Documents 5, 6, 7). As an example, Patent Document 1 discloses a method and an apparatus for producing a graphene transparent conductive film. In this method, while winding up copper foil, which is a conductive flexible substrate for film formation, an electric current is applied directly to the copper foil to heat it to a temperature above the graphene production temperature, and graphene is produced by contacting the surface of the copper foil with a carbon source material, which is a raw material. In other words, this is a method of continuously synthesizing graphene on the surface of the copper foil by a thermal CVD method in which the copper foil is heated to 900 to 1000° C. by current heating while winding it up, and exposed to a mixed gas of argon and hydrogen containing methane gas as a carbon source. However, this method is basically a thermal CVD synthesis, so the problem of long process time remains unsolved, and the development of a synthesis method with higher throughput has been required.

In addition, Patent Document 2 discloses a high-throughput graphene production method using a roll-to-roll plasma CVD method with copper foil as a film-forming substrate. It has been reported that this method allows continuous graphene synthesis at a copper foil winding speed of 2 to 5 mm per second. On the other hand, when the graphene synthesized by this method was analyzed by Raman spectroscopy, it was found to have a high D-band intensity due to defects and to have low crystal quality with many defects. The number of layers was also in the order of several to several ten layers, and it was not possible to obtain single-layer or double-layer graphene, so-called atomic layers. In addition, when a transparent conductive film was produced using this graphene and measured, the sheet resistance was very high at 1×10⁵Ω. Thus, this method does not allow graphene with high crystal quality to be obtained.

### PRIOR ART DOCUMENTS

### Patent Documents

[Patent Document 1] JP Patent No. 5862080 [Patent Document 2] JP Patent No. 5692794

### Non-Patent Documents

[Non-patent Document 1] Kumi Yamada, Chemistry and Industry, 61 (2008) pp. 1123-1127.
[Non-patent document 2] Y. Wu, P. Qiao, T. Chong, Z. Shen, Adv. Mater. 14 (2002) pp. 64-67.
[Non-patent Document 3] Alfonso Reina, Xiaoting Jia, John Ho, Daniel Nezich, Hyungbin Son, Vladimir Bulovic, Mildred S. Dresselhaus, Jing Kong, Nano letters, 9 (2009) pp. 30-35.
[Non-patent document 4] Xuesong Li, Yanwu Zhu, Weiwei Cai, Mark Borysiak, Boyang Han, David Chen, Richard D. Piner, Luigi Colombo, Rodney S. Ruoff, Nano Letters, 9 (2009) pp. 4359-4363.
[Non-Patent Document 5] Low-temperature graphene synthesis using microwave plasma CVD, Takatoshi Yamada, Jacho Kim, Masatou Ishihara, Masataka Hasegawa, J. Phys. D 46 (2013) 063001 (8 pp).
[Non-Patent Document 6] Production of a 100-m-long high-quality graphene transparent conductive film by roll-to-roll chemical vapor deposition and transfer process, T. Kobayashi, M. Bando, N. Kimura, K. Shimizu, K. Kadono, N. Umczu, K. Miyahara, S. Hayazaki, S. Nagai, Y. Mizuguchi, Y. Murakami, D. Hobara, Appl. Phys. Lett. 2013, 102, 023112.
[Non-Patent Document 7] High-speed roll-to-roll manufacturing of graphene using a concentric tube CVD reactor, Erik S. Polsen, Daniel Q. McNerny, B. Viswanath, Sebastian W. Pattinson, A. John Hart Scientific Reports 5 (2015) 10257.

### Problems to be Solved by the Invention

In order to establish a method for synthesizing graphene with high crystal quality and with higher throughput, the inventors combined the methods of Patent Document 1 and Patent Document 2, applied an electric current to copper foil, heated the copper foil by Joule heating to a temperature above the graphene formation temperature, and conducted a graphene synthesis test by irradiating a plasma generated by exciting a gas in which methane gas, a carbon source, is mixed with hydrogen, or a gas in which methane gas, a carbon source, is mixed with hydrogen and argon, while continuously winding the copper foil. As a result, it was confirmed that the graphene formed by this method had low crystal quality and contained many defects. It was also found that the cause of this low crystal quality was radiation damage to the graphene caused by ion bombardment by plasma irradiation during the graphene formation process.

The present invention has been made in consideration of the above circumstances, and aims to provide a graphene film manufacturing apparatus that can solve the problem of defects being generated in the graphene due to ion bombardment from the plasma, resulting in significant deterioration of crystallinity, when graphene is synthesized by the so-called roll-to-roll method in which a metal substrate for graphene synthesis, such as copper foil heated by electrical current heating, is irradiated with plasma while being continuously wound up, and that can continuously form single-layer and double-layer graphene with higher crystallinity with high throughput.

### Means for Solving Problem

As a result of extensive research conducted by the inventors to achieve the above object, the present invention provides a graphene film manufacturing device that suppresses the occurrence of radiation damage to graphene caused by ion bombardment from plasma irradiation and forms highly crystalline single-layer and double-layer graphene with high throughput when continuously synthesizing graphene by a so-called roll-to-roll method in which a heated metal substrate is continuously wound while being irradiated with plasma.

The present invention has been completed based on these findings, and is as follows.
[1] A graphene film manufacturing apparatus comprising a plasma generating device that generates plasma in a processing vessel, a metal substrate for graphene film formation installed in the processing vessel and a device for continuously feeding and winding the substrate, a Joule heating device for Joule heating the metal substrate for graphene film formation installed in the processing vessel, and a substrate cover for covering the metal substrate for graphene film formation.
[2] A graphene film manufacturing apparatus comprising a plasma generating device that generates plasma in a processing vessel, a metal substrate for graphene film formation installed in the processing vessel and a device for continuously feeding and winding the substrate, a Joule heating device for Joule heating the metal substrate for graphene film formation installed in the processing vessel, and a substrate cover for covering the metal substrate for graphene film formation, the substrate cover having an opening.
[3] A graphene film manufacturing apparatus comprising: a plasma generating device that generates plasma in a processing vessel; a metal substrate for graphene film formation installed in the processing vessel and a device for continuously feeding and winding the substrate; a Joule heating device for Joule heating the metal substrate for graphene film formation installed in the processing vessel; and a substrate cover that covers the metal substrate for graphene film formation, the substrate cover having an opening, and the position and length of the opening being set according to the winding speed of the metal substrate that is heated by Joule heating while being continuously wound up.
[4] A graphene film manufacturing apparatus comprising: a plasma generating device that generates plasma in a processing vessel; a metal substrate for graphene film formation installed in the processing vessel and a device for continuously feeding and winding the substrate; a Joule heating device for Joule heating the metal substrate for graphene film formation installed in the processing vessel; and a substrate cover that covers the metal substrate for graphene film formation, the substrate cover having an opening, and the position and/or length of the opening being set according to the winding speed of the metal substrate that is heated by Joule heating while being continuously wound up.

### Effect of the Invention

The device of the present invention makes it possible to suppress the occurrence of radiation damage to graphene caused by ion bombardment, and to synthesize highly crystalline single-layer and double-layer graphene continuously and with high throughput using a roll-to-roll method.

### BRIEF DESCRIPTIONS OF DRAWINGS

FIG. 1 A schematic diagram of a graphene film manufacturing apparatus according to one example of the present invention.

FIG. 2 A Raman spectroscopy spectrum according to this example.

FIG. 3 A Raman spectroscopy spectrum according to this example.

FIG. 4 A Raman spectroscopy spectrum according to this example.

FIG. 5 A Raman spectroscopy spectrum according to this example.

FIG. 6 A diagram of the substrate cover of a graphene film manufacturing apparatus according to one example of the present invention.

### SUMMARY OF THE INVENTION

The graphene film manufacturing apparatus according to one example of the present invention is characterized by having a plasma generating device that generates plasma in a processing vessel, a metal substrate for graphene film formation installed in the processing vessel, a feed roll and a take-up roll as devices for continuously feeding and winding the substrate, a first electrode roll and a second electrode roll as Joule heating devices for Joule heating the metal substrate for graphene film formation installed in the processing vessel, and a substrate cover that is heated by Joule heating while continuously winding and has a mechanism that can change the length and position of an opening in response to the change in the heated area with the winding speed.

The present invention will be described below with reference to the drawings. However, the present invention is not limited thereto.

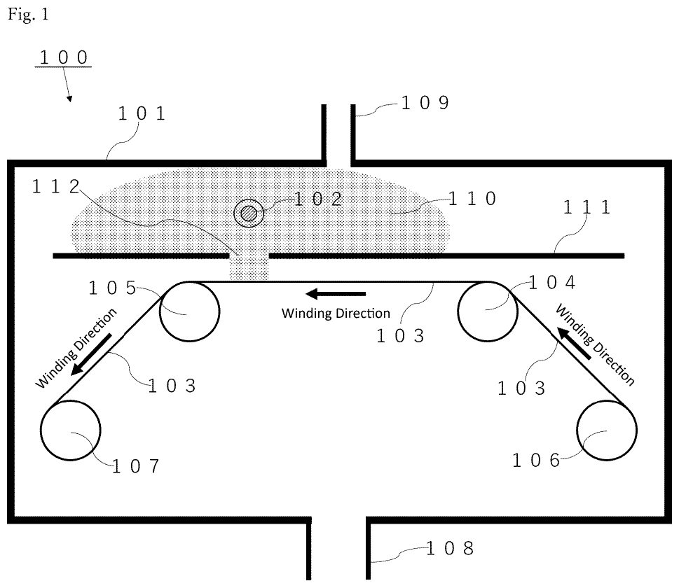

In FIG. 1, 100 is the graphene film manufacturing apparatus of the present invention. This figure is a diagram showing one example, in which 101 is the processing vessel processing vessel, 102 is the plasma generating device, 103 is the metal substrate, 104 is the first electrode roll for electrically heating the metal substrate 103, 105 is the second electrode roll for electrically heating the metal substrate 103, 106 is the delivery roll for the metal substrate 103, 107 is the winding roll for the metal substrate 103, 108 is the exhaust port, 109 is the gas introduction tube for plasma processing, 111 is the substrate cover, and 112 is the opening provided in the substrate cover. The hatched portion of 110 is the plasma, and the metal substrate 103 is irradiated through the opening 112.

The plasma processing using the graphene film manufacturing apparatus according to one example of the present invention may be a plasma processing using a mixture of hydrogen gas and methane gas under reduced pressure, and may be a high-frequency inductively coupled plasma processing, a capacitively coupled high-frequency plasma processing, a microwave surface wave plasma processing, a microwave plasma processing, or a direct current plasma processing.

These plasma power sources use high-frequency waves, microwaves, direct current, etc., and generate chemically active ions and radicals (excited atoms and molecules) by discharging a raw material gas at a certain pressure and turning it into a plasma state. The plasma CVD method is a technology in which active particles generated in the plasma promote chemical reactions on the substrate surface, and a thin film can be formed in a short time. On the other hand, in thermal CVD technology, the gas encounters a catalytically active substrate at a high temperature and decomposes for the first time, and it takes longer to form a thin film than with plasma. For this reason, thermal CVD technology generally takes a longer process than the plasma CVD method.

In order to form a graphene film without changing the surface shape of the metal substrate and without causing the metal to evaporate, it is necessary to heat the substrate to a temperature lower than the melting point of the metal and perform plasma treatment. For example, in the case of a copper foil substrate, it is necessary to perform treatment at a temperature lower than the melting point of copper (1085° C.).

Normal plasma treatment is performed at a pressure of 2×10³ to 1×10⁴ Pa. At this pressure, the plasma does not easily diffuse and is concentrated in a narrow area, so the temperature of the neutral gas in the plasma greatly exceeds 1000° C. As a result, the temperature of the copper foil substrate becomes high locally, causing a large amount of copper to evaporate from the copper foil surface, making it impossible to produce graphene. In addition, there is a limit to how uniformly the plasma region can be expanded, making it difficult to form a highly uniform graphene over a large area.

Therefore, in order to suppress excessive rise of the temperature in the copper foil substrate during film formation and to form a highly uniform graphene film over a large area, plasma treatment at a lower pressure is necessary. In other words, it is necessary to increase the mean free path of active species in plasma by lowering the pressure and to promote the transport of active carbon radicals, hydrogen radicals, and the like to the substrate. As conditions for plasma treatment to synthesize graphene, the pressure is 50 Pa or less, preferably 10 to 30 Pa, and more preferably 15 to 25 Pa. As conditions for the plasma treatment to synthesize graphene, the temperature of the copper foil is 1085° C. or less, preferably 900 to 1050° C., and more preferably 980 to 1000° C. As conditions for the plasma treatment to synthesize graphene, the gas used is a mixed gas of methane and hydrogen, and the concentration of methane is preferably 0.1 to 5%, and more preferably 0.5 to 2%.

The graphene film manufacturing apparatus of the present invention 100 shown in FIG. 1 has a metal processing vessel 101, to which a vacuum exhaust device (not shown) and a pressure adjustment device (not shown) are connected via the exhaust port 108. The processing vessel 101 is also provided with a plasma generating device 102 consisting of a dielectric antenna cover for introducing radio frequency (RF) airtightly attached via a metal support member (not shown) and an antenna attached inside the dielectric antenna cover. The plasma generating device 102 has a linear structure with a length of 300 mm in the depth direction of the figure. A 13.56 MHz radio frequency (RF) power source (not shown) installed outside the processing vessel 101 is connected to the plasma generating device 102, and gas required for plasma processing is introduced through the gas introduction tube 109 for introducing the gas into the processing vessel 101, and power is input from the radio frequency (RF) power source to the plasma generating device to excite the plasma 110 for plasma processing (hatched part).

In addition, inside the processing vessel, the metal substrate 103 wound around the delivery roll 106 is delivered, mechanically and electrically contacted with the first electrode roll 104 and the second electrode roll 105, and arranged to be wound around the winding roll 107. The moving speed and tension of the metal substrate 103 are adjusted by the winding speed of the winding roll 107 and the braking force of the delivery roll 106, which are controlled so that slack does not occur in the metal substrate 103 at the desired moving speed. The first electrode roll 104 and the second electrode roll 105 are connected to a DC power source (not shown) installed outside the processing vessel 101, and are configured so that Joule heating can be performed by passing electricity between the first electrode roll 104 and the second electrode roll 105 while winding the metal substrate 103.

The plasma generating device 102 is installed at a position 255 mm from the center of the first electrode roll 104 and the second electrode roll 105 toward the second electrode roll 105. The distance between the plasma generating device 102 and the metal substrate 103 is 125 mm. The plasma 110 excited by the plasma generating device 102 has a spread large enough to expose almost the entire surface of the metal substrate 103 between the first electrode roll 104 and the second electrode roll 105. The metal substrate cover 111 is disposed between the metal substrate 103 and the plasma generating device 102 to be parallel to the metal substrate 103. This substrate cover 111 can be removed as necessary.

In this example, the distance between the centers of the first electrode roll 104 and the second electrode roll 105 is 630 mm. When a rolled copper foil with a thickness of 10.2 μm is used as the metal substrate 103 and Joule-heated at zero moving speed without being wound up, it was confirmed that the metal substrate 103 is red-hot in a range of 530 mm in length, centered exactly at the midpoint between the first electrode roll 104 and the second electrode roll 105. When measured with a radiation thermometer, the temperature of the red-hot part was 1000° C. On the other hand, the copper foil near the first electrode roll 104 and the second electrode roll 105 was not red-hot, and the temperature of this part of the copper foil was measured with a radiation thermometer to be 200° C. or less, which was lower than the temperature of the red-hot part. In this way, it was found that the metal substrate 103 is not heated uniformly between the first electrode roll 104 and the second electrode roll 105, and the above-mentioned temperature distribution occurs. Next, when the copper foil was Joule-heated while being wounded, it was confirmed that the center of the red-hot part moved toward the second electrode roll 105 and the length of the red-hot part became smaller as the winding speed increased. When the copper foil was Joule heated while being wound at 10 mm per second, the center of the red-hot part moved 130 mm from the center of the first electrode roll 104 and the second electrode roll 105 toward the second electrode roll 105, and the length of the red-hot part became 260 mm. Thus, it was found that the position and length of the red-hot part changed depending on the winding speed when Joule heating was performed while the metal substrate 103 was being wound and when Joule heating was performed in a stopped state without being wound.

When a rolled copper foil with a thickness of 10.5 μm was used as the metal substrate 103, it was found that the winding speed V (mm/sec), the position Y (mm) of the center of the red-hot part, and the length W (mm) of the red-hot part had the following relationships of Equation 1 and Equation 2, respectively, when V was in the range of 0 to 11 mm/sec.

$$Y = 13 \times V \qquad Equation 1$$

$$W = - 27 \times V + 530 \qquad Equation 2$$

In this example, a commercially available rolled copper foil was used as the metal substrate. The copper foil used was a tough pitch copper foil with a thickness of 10.2 microns and a width of 250 mm manufactured by Fukuda Metal Foil and Powder Co., Ltd. The surface of this copper foil was treated for rust prevention with an organic substance such as BTA. Therefore, prior to the formation of the graphene film, the rust prevention treatment was removed by the following method. First, a 30 m long copper foil wound around the delivery roll 106 was loaded into the film formation device and arranged so that it would be wound around the winding roll 107 via the first electrode roll 104 and the second electrode roll 105. Next, after evacuating the graphene production device 100, the copper foil between the first electrode roll 104 and the second electrode roll 105 was heated by direct current using a DC power source connected to the first electrode roll 104 and the second electrode roll 105. The applied current was adjusted to a maximum temperature of about 1000° C., and the copper foil was heated while being wound around the winding roll 107 at 10 mm per second. This heating process removed the rust-proofing treatment on the copper foil surface. After this, the copper foil wound around the winding roll 107 was moved in the reverse direction and rewound again around the delivery roll 106. This completed the preparation for graphene synthesis. Note that the substrate cover 111 may be installed or removed during this preparation process.

In the following examples, Raman spectroscopy was measured. The measuring device was a Horiba, Ltd. XploRA model, with an excitation laser wavelength of 532 nm, a laser beam spot size of 1 μm in diameter, 600 gratings in the spectrometer, and a laser source output of 9.8 mW. No attenuator was used. The aperture was 300 μm, the slit was 100 μm, and the objective lens was 100×. The exposure time was 5 seconds, and 5 measurements were accumulated to obtain a spectrum.

It has been shown in non-patent literature (L. M. Malard, M. A. Pimenta, G. Dresselhaus and M. S. Dresselhaus, Physics Reports 473 (2009) 51-87, etc.) that the peak positions of the 2D band, G band, D band, and D′ band depend on the number of layers of the graphene film and the excitation wavelength of the laser when measuring the Raman spectroscopy spectrum. For example, in the case of a single-layer graphene film excited by a laser with an excitation wavelength of 514.5 nm, the peak positions of the 2D band, G band, D band, and D′ band are around 2700 cm⁻¹, 1582 cm⁻¹, 1350 cm⁻¹, and 1620 cm⁻¹. The G band is due to normal six-membered rings, and the 2D band is due to an overtone of the D band. The D band is a peak caused by defects in normal six-membered rings. The D′ band is also a peak induced by defects and is thought to be caused by the edge part of graphene of several to several tens of layers (see G. Cancado, M. A. Pimenta, B. R. A. Neves, M. S. S. Dantas, A. Jorio, Phys. Rev. Lett. 93 (2004) pp. 247401_1-4). When both the G band and the 2D band peaks are observed in the Raman spectroscopy spectrum, the film is identified as graphene (see Non-Patent Document 3). It is generally known that the 2D band shifts to a higher wavenumber and the half-width increases as the number of graphene layers increases. Furthermore, the 2D band shifts to a higher wavenumber as the laser excitation wavelength decreases.

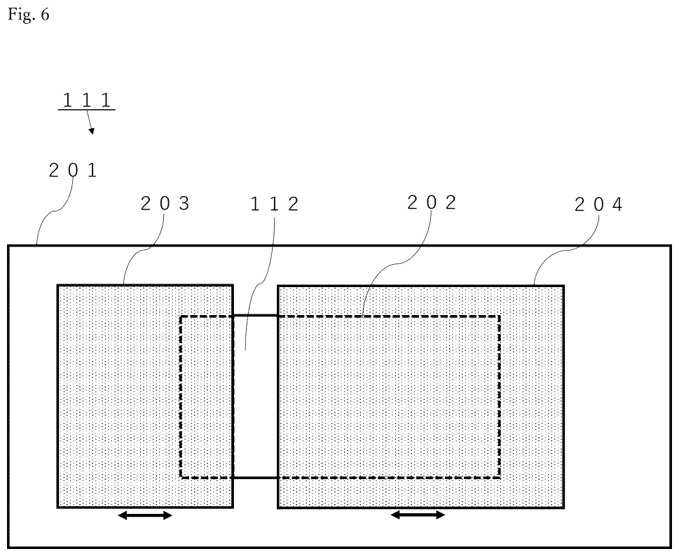

Details of the substrate cover 111 of the graphene film manufacturing apparatus according to one example of the present invention will be described with reference to FIG. 6. FIG. 6 is a configuration diagram of the substrate cover 111. Thus, the substrate cover 111 has a structure in which the first slide plate 203 and the second slide plate 204 are installed on the substrate cover frame 201 having the substrate cover hole 202 drawn by a dashed line in the figure. The first slide plate 203 and the second slide plate 204 are each drawn with hatching in the figure. The first slide plate 203 and the second slide plate 204 are installed to cover the substrate cover hole 202, and the position can be adjusted by sliding in the left and right directions in the figure (the direction of the arrow in the figure). This makes it possible to realize a state without the opening 112, and also to set the opening 112 having any position and length. The substrate cover frame 201, the first slide plate 203, and the second slide plate 204 are made of stainless steel. This substrate cover 111 can be removed as necessary.

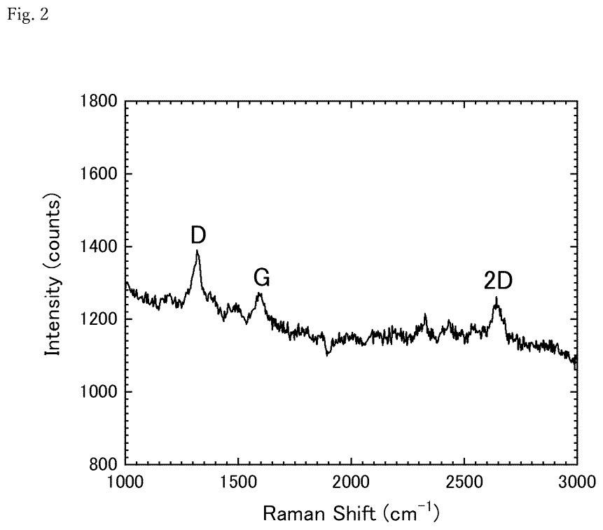

First, plasma was generated with the substrate cover 111 removed, and the copper foil was plasma-treated while being wound at 0 to 10 mm per second. The gas used in the plasma treatment was a mixture of methane and hydrogen with a methane concentration of 1%, and the pressure was 20 Pa. The temperature of the red-hot part of the copper foil was 1000° C. FIG. 2 shows the Raman spectroscopy spectrum of the graphene film formed on the copper foil surface by this plasma treatment while being wound at 10 mm per second. As shown, the G band and 2D band characteristic of graphene were observed, but the D band caused by defects was very strong. Therefore, the synthesized graphene had poor crystallinity and was of poor quality. With the substrate cover 111 removed, graphene with poor crystalline as shown in FIG. 2 was synthesized at winding speeds of 0 to 10 mm per second.

It has been shown in a patent document (JP Patent No. 6411112) that graphene with high crystal quality can be synthesized by heating the copper foil substrate for graphene deposition by Joule heating when synthesizing graphene by plasma CVD and then covering the copper foil substrate for graphene deposition with a substrate cover.

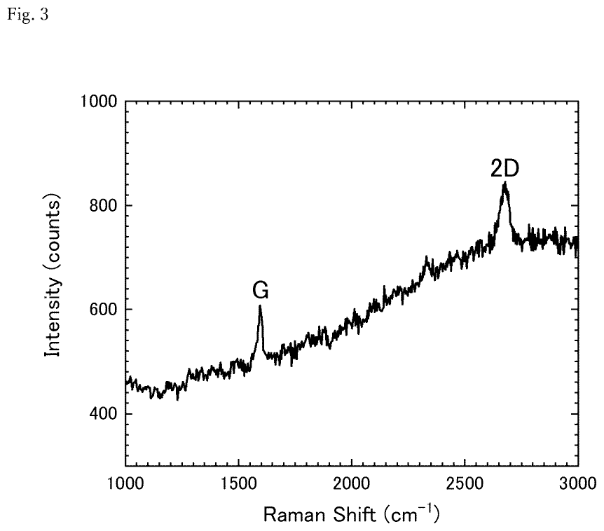

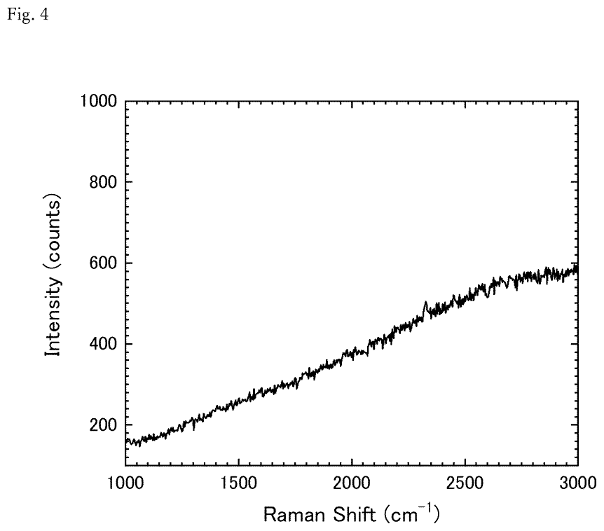

In this example, the substrate cover 111 without the opening 112 was then installed. The substrate cover 111 was installed between the metal substrate 103 and the plasma generating device 102 so as to be parallel to the copper foil, which is the metal substrate 103. The distance between the substrate cover 111 and the copper foil was 50 mm. In this state, the metal substrate was plasma-treated while being wound at 0 to 10 mm per second. The gas used for the plasma treatment was a mixture of methane and hydrogen with a methane concentration of 1%, and the pressure was 20 Pa. The temperature of the red-hot part of the copper foil was 1000° C. FIG. 3 shows the Raman spectroscopy spectrum of a graphene film formed on the copper foil surface by plasma treatment while being wound at 2 mm per second. As described above, the D band caused by defects was hardly observed, which indicates that a graphene film with good crystallinity was formed. In all plasma treatments with a copper foil winding speed of 0 to 2 mm per second, the formation of a graphene film with good crystallinity as shown in FIG. 3 was confirmed. The half-width of the 2D band peak was 43 cm⁻¹, and according to a non-patent document (Ryuichi Kato, Kazuo Tsugawa, Yuki Okigawa, Masatou Ishihara, Takatoshi Yamada, Masataka Hasegawa, Carbon 77 (2014) 323-328), the number of layers of this graphene was two, and it was found that bilayer graphene was formed. Although the Raman spectrum is not shown, in a synthesis experiment with a methane concentration of 0.5%, graphene with a half-width of the 2D band of 31 cm⁻¹ was synthesized, and according to the above non-patent document, the number of layers of this graphene was one, and it was found that single-layer graphene is able to be synthesized. On the other hand, FIG. 4 shows a typical Raman spectrum when plasma treatment was performed with 1% methane and a copper foil winding speed of 3 to 10 mm per second. As shown in this figure, no Raman peaks due to the graphene film were observed, and the formation of a graphene film could not be confirmed at a winding speed of 3 to 10 mm per second.

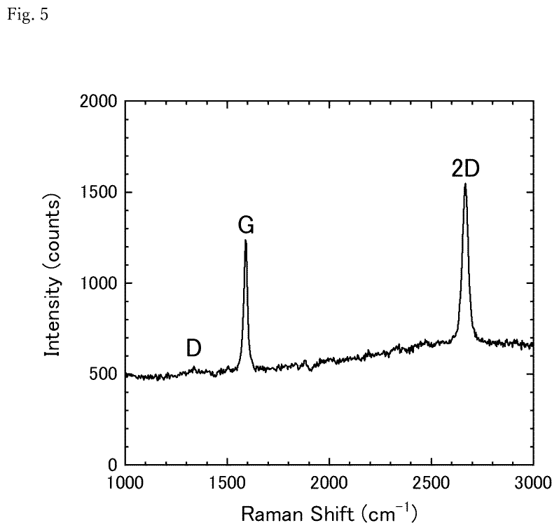

Next, the substrate cover 111 with the opening 112 was installed. The substrate cover was installed between the metal substrate 103 and the plasma generator 102 to be parallel to the copper foil, which is the metal substrate 103. The distance between the substrate cover 111 and the copper foil was 50 mm. The opening 112 was provided so that the plasma generated by the plasma generating device 102 was exposed to the red-hot part of the copper foil. The center position of the opening 112 of the substrate cover was aligned with the center of the red-hot part of the copper foil, and the length of the opening 112 of the substrate cover along the copper foil winding direction was aligned with the length of the red-hot part of the copper foil. The center position of the opening 112 of the substrate cover was determined according to Equation 1, and the length of the opening 112 of the substrate cover was determined according to Equation 2. The depth of the opening 112 of the substrate cover was 270 mm. In this example, the winding speed of the copper foil was set to 10 mm per second. In this case, the center of the opening 112 of the substrate cover was set to a position 130 mm from the center of the first electrode roll 104 and the second electrode roll 105 toward the second electrode roll 105 according to Equation 1. The length of the opening 112 of the substrate cover was set to 260 mm according to Equation 2. As a result, the red-hot part of the copper foil was plasma-treated, and the other parts with lower temperatures were not directly exposed to the plasma. In this state, the plasma treatment was performed while the copper foil was being wounded. The gas used for the plasma treatment was a mixture of methane and hydrogen with a methane concentration of 1%, and the pressure was 20 Pa. The temperature of the red-hot part of the copper foil was 1000° C. FIG. 5 shows the Raman spectroscopy spectrum of the graphene film formed on the copper foil surface by this treatment. Thus, the intensity of the D band caused by defects is very small, indicating that a graphene film with good crystallinity was formed. The half-width of the 2D band peak was 32 cm⁻¹, and according to a non-patent document (Ryuichi Kato, Kazuo Tsugawa, Yuki Okigawa, Masatou Ishihara, Takatoshi Yamada, Masataka Hasegawa, Carbon 77 (2014) 323-328), the number of layers of this graphene was 1, indicating that single-layer graphene was formed. Although the Raman spectrum is not shown, in a synthesis experiment in which the methane concentration was 2%, graphene with a half-width of the 2D band of 42 cm⁻¹ was synthesized, and according to the above non-patent document, the number of layers of this graphene was 2, indicating that bilayer graphene could be synthesized.

The formation of a graphene film was confirmed. The half-width of the 2D band peak was 43 cm⁻¹, and according to a non-patent document (Ryuichi Kato, Kazuo Tsugawa, Yuki Okigawa, Masatou Ishihara, Takatoshi Yamada, Masataka Hasegawa, Carbon 77 (2014) 323-328), the number of layers of this graphene was two, and it was found that bilayer graphene was formed. Although the Raman spectrum is not shown, in a synthesis experiment in which the concentration of methane was 0.5%, graphene with a half-width of the 2D band of 31 cm⁻¹ was synthesized, and according to the above non-patent document, the number of layers of this graphene was one, and it was found that single-layer graphene was synthesized. On the other hand, FIG. 4 shows a typical Raman spectrum when plasma treatment was performed with 1% methane and a copper foil winding speed of 3 to 10 mm per second. Thus, no Raman peak due to the graphene film was observed, and the formation of a graphene film could not be confirmed at a winding speed of 3 to 10 mm per second.

In this example, the center position and length of the opening 112 in the substrate cover 111 are determined using Equation 1 and Equation 2, respectively, according to the winding speed of the copper foil, which is the metal substrate 103, and the positions of the first slide plate 203 and the second slide plate 204 are adjusted to set the opening 112. In this way, it is preferable to determine the center position and length of the opening 112 provided in the substrate cover 111 using Equation 1 and Equation 2, respectively, so that it coincides with the center position and length of the red-hot part according to the winding speed of the copper foil, which is the metal substrate 103. In other words, the graphene film manufacturing apparatus of the present invention is a graphene film manufacturing apparatus characterized in that the substrate cover 111 is provided with the opening 112, and the position and length of the opening are set according to the winding speed of the metal substrate 103, which is heated by Joule heating while being continuously wound.

On the other hand, even if the substrate cover 111 is provided with the opening 112 that does not have either the central position or the length determined by Equation 1 and Equation 2, respectively, or has either one of them, graphene with better crystallinity may be formed compared to the state without the substrate cover 111. Furthermore, even if the substrate cover 111 is provided with the opening 112 that does not have either the central position or the length determined by Equation 1 and Equation 2, respectively, or has either one of them, a graphene film may be formed at a high winding speed at which the formation of a graphene film could not be confirmed when the substrate cover 111 without an opening was installed. That is, the graphene film manufacturing device may be characterized in that the substrate cover 111 is simply provided with the opening 112. Furthermore, the graphene film manufacturing device may be characterized in that the substrate cover 111 is provided with the opening 112, and the position and/or length of the opening is set according to the winding speed of the metal substrate 103 that is heated by Joule heating while being continuously wound.

In the example of the present invention, the positions of the first slide plate 203 and the second slide plate 204 were adjusted manually. On the other hand, by introducing computer control and equipping a mechanism for automatically adjusting the positions of the first slide plate 203 and the second slide plate 204 so that the position and length of the opening 112 correspond to the winding speed of the metal substrate 103, it is possible to make a more highly functional graphene film synthesis device. For example, by adjusting the supply amount of raw material gas and the winding speed of the metal substrate 103, it is possible to adjust the number of layers of the graphene film to be synthesized. Therefore, by equipping an automatic position adjustment mechanism for the first slide plate 203 and the second slide plate 204 so that the position and length of the opening 112 correspond to the winding speed of the metal substrate 103, it is possible to synthesize graphene films with different numbers of layers in successive synthesis processes.

The device of the present invention makes it possible to synthesize graphene with good crystallinity at a high throughput. This makes it possible to realize a variety of products using graphene, such as transparent conductive films for touch panel applications, semiconductor devices or electronic devices such as transistors and integrated circuits, transparent electrodes and electrochemical electrodes that require a large area, and various highly sensitive sensors.

### REFERENCE SIGNS LIST

100 Graphene film manufacturing apparatus of the present invention
101 Processing vessel
102 Plasma generating device
103 Metal substrate
104 First electrode roll
105 Second electrode roll
106 Delivery roll
107 Winding roll
108 Exhaust port
109 Gas introduction tube
110 Plasma
111 Substrate cover
112 Opening
201 Substrate cover frame
202 Substrate cover hole
203 First slide plate
204 Second slide plate

1. A graphene film manufacturing apparatus comprising:
a plasma generation device configured to generate plasma in a processing vessel;
a metal substrate for graphene film formation which is installed in the processing vessel;
a device configured to continuously deliver and wind said metal substrate;
a Joule heating device configured to Joule-heat the metal substrate installed in the processing vessel; and
a substrate cover that covers the metal substrate for the graphene film formation.

2. A graphene film manufacturing apparatus comprising:
a plasma generation device configured to generate plasma in a processing vessel;
a metal substrate for graphene film formation which is installed in the processing vessel;
a device configured to continuously deliver and wind said metal substrate;
a Joule heating device configured to Joule-heat the metal substrate installed in the processing vessel; and
a substrate cover that covers the metal substrate for graphene film formation,
wherein said substrate cover has an opening.

3. A graphene film manufacturing apparatus comprising:
a plasma generation device configured to generate plasma in a processing vessel;
a metal substrate for graphene film formation which is installed in the processing vessel;
a device configured to continuously deliver and wind said metal substrate;
a Joule heating device configured to Joule-heat the metal substrate installed in the processing vessel;
a substrate cover that covers the metal substrate for graphene film formation,
wherein the substrate cover has an opening, and
wherein a position or length of the opening of the substrate cover is set according to a winding speed of the metal substrate that is Joule-heated while being continuously wound up.

4. The graphene film manufacturing apparatus according to claim 3, wherein each of the position and the length of the opening of the substrate cover is set according to the winding speed of the metal substrate that is Joule-heated while being continuously wound up.
